(19) United States
(12) Patent Application Publication
(10) Pub. No.: US 2026/0031117 A1
(43) Pub. Date: Jan. 29, 2026

(54) DOUBLE BANK PREFETCH

(71) Applicant: Micron Technology, Inc., Boise, ID (US)

(72) Inventor: Glen E. Hush, Boise, ID (US)

(21) Appl. No.: 19/268,260

(22) Filed: Jul. 14, 2025

Related U.S. Application Data
(60) Provisional application No. 63/676,351, filed on Jul. 27, 2024.

(51) Int. Cl. G11C 7/10; G11C 7/08

(52) U.S. Cl. CPC G11C 7/1039; G11C 7/08; G11C 7/1063

(57) ABSTRACT

Double bank prefetch is described herein. A first sense amplifier strip couped to the array of memory cells and the column decoder can receive first data from the array of memory cells and provide the first data to a first processing unit (PU) of the apparatus using the address. The second sense amplifier strip coupled to the array and the column decoder can receive second data from the array of memory cells and provide the second data to a second PU of the apparatus using the address.

### PRIORITY INFORMATION

This application claims the benefit of U.S. Provisional Application No. 63/676,351, filed on Jul. 27, 2024, the contents of which are incorporated herein by reference.

### TECHNICAL FIELD

The present disclosure relates generally to memory, and more particularly to apparatuses and methods associated with performing a double bank prefetch.

### BACKGROUND

Memory devices are typically provided as internal, semiconductor, integrated circuits in computers or other electronic devices. There are many different types of memory including volatile and non-volatile memory. Volatile memory can require power to maintain its data and includes random-access memory (RAM), dynamic random access memory (DRAM), and synchronous dynamic random access memory (SDRAM), among others. Non-volatile memory can provide persistent data by retaining stored data when not powered and can include NAND flash memory, NOR flash memory, read only memory (ROM), Electrically Erasable Programmable ROM (EEPROM), Erasable Programmable ROM (EPROM), and resistance variable memory such as phase change random access memory (PCRAM), resistive random access memory (RRAM), and magnetoresistive random access memory (MRAM), among others.

Memory is also utilized as volatile and non-volatile data storage for a wide range of electronic applications. Non-volatile memory may be used in, for example, personal computers, portable memory sticks, digital cameras, cellular telephones, portable music players such as MP3 players, movie players, and other electronic devices. Memory cells can be arranged into arrays, with the arrays being used in memory devices.

### BRIEF DESCRIPTION OF THE DRAWINGS

FIG. 1 is a block diagram of an apparatus in the form of a computing system including a memory device in accordance with a number of embodiments of the present disclosure.

FIG. 2 is a block diagram illustrating a plurality of subarrays in accordance with a number of embodiments of the present disclosure.

FIG. 3 is a block diagram illustrating a bank in accordance with a number of embodiments of the present disclosure.

FIG. 4 illustrates an example flow diagram of a method for performing a double bank prefetch in accordance with a number of embodiments of the present disclosure.

FIG. 5 illustrates an example machine of a computer system within which a set of instructions, for causing the machine to perform any one or more of the methodologies discussed herein, can be executed.

### DETAILED DESCRIPTION

The present disclosure includes apparatuses and methods associated with performing a double bank prefetch. Memory can include an array of memory cells, a column decoder, a first sense amplifier strip, and a second sense amplifier strip. The column decoder can provide an address to the first sense amplifier strip and the second sense amplifier strip. The first sense amplifier strip can be coupled to the array and the column decoder. The first sense amplifier strip can receive first data from the array of memory cells and can provide the first data to a first processing unit (PU) using the address. The second sense amplifier strip can also be coupled to the array and the column decoder. The second sense amplifier strip can receive second data from the array of memory cells and can provide the second data to a second PU using the address.

In previous approaches, a bank of a memory device can provide data to a single PU. Multiple PUs may be incapable of being coupled to the bank given that the size of the prefetch of the bank may be limited. The size of the prefetch of the bank may not be sufficient to provide data to multiple PUs. The size of the prefetch may be limited due to the use of a single data sense amplifier (DSA) unit to output or input data to the array of memory cells.

As used herein, a sense amplifier strip can include a plurality of sense amplifiers. The plurality of sense amplifiers can sense signals provided by the memory cells of an array. The plurality of sense amplifiers can amplify the signals provided by the memory cells. The sense amplifier strip can provide the amplified signals to the DSA unit. The DSA unit can include hardware. The DSA unit can further amplify the signals and can drive the signals to I/O circuitry.

In order to address these and other deficiencies of previous approaches, embodiments of the present disclosure provide for the implementation of multiple DSA units. The subarrays of an array of memory cells can be configured to provide data to the multiple DSA units. For example, a first portion of the subarrays can provide data to a first DSA unit via a first sense amplifier strip. A second portion of the subarrays can provide data to a second DSA unit via a second sense amplifier strip. The first DSA unit can provide data to a first PU. The second DSA unit can provide data to a second PU.

The first PU and the second PU can receive data and can perform a number of operations on the data to generate different data (e.g., output data). For example, the first PU can perform a first number of operations to generate first output data. The second PU can perform a second number of operations to generate second output data. The PUs can be used to implement one or more artificial neural networks (ANNs). The data received by the PUs can be weights and/or inputs to an ANN, for example.

As used herein, ANNs can provide learning by forming probability weight associations between an input and an output. The probability weight associations can be provided by a plurality of nodes that comprise the ANN. The nodes together with weights, biases, and activation functions can be used to generate an output of the ANN based on the input to the ANN. A plurality of nodes of the ANN can be grouped to form layers of the ANN.

As used herein, artificial intelligence (AI) refers to the ability to improve an apparatus through “learning” such as by storing patterns and/or examples which can be utilized to take actions at a later time. Deep learning refers to a device's ability to learn from data provided as examples. Deep learning can be a subset of AI. Neural networks, among other types of networks, can be classified as deep learning. Improving the efficiency at which ANNs are executed can improve a function of a memory device executing the ANN and the function of the device in which the memory device is implemented. For example, improving the latency, power consumption, and/or throughput of the memory device implementing the ANN can cause an improvement to the latency, power consumption, and/or throughput of a memory system.

As used herein, “a number of” something can refer to one or more of such things. For example, a number of memory devices can refer to one or more memory devices. A “plurality” of something intends two or more. Additionally, designators such as “N,” as used herein, particularly with respect to reference numerals in the drawings, indicates that a number of the particular feature so designated can be included with a number of embodiments of the present disclosure.

The figures herein follow a numbering convention in which the first digit or digits correspond to the drawing figure number and the remaining digits identify an element or component in the drawing. Similar elements or components between different figures may be identified by the use of similar digits. As will be appreciated, elements shown in the various embodiments herein can be added, exchanged, and/or eliminated so as to provide a number of additional embodiments of the present disclosure. In addition, the proportion and the relative scale of the elements provided in the figures are intended to illustrate various embodiments of the present disclosure and are not to be used in a limiting sense.

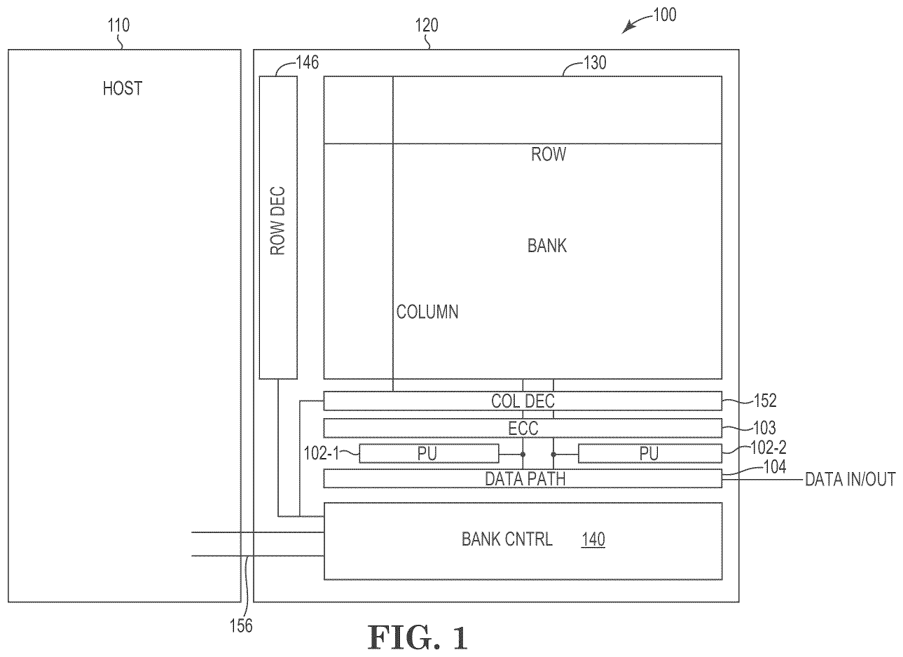

FIG. 1 is a block diagram of an apparatus in the form of a computing system 100 including a memory device 120 in accordance with a number of embodiments of the present disclosure. As used herein, a memory device 120, a bank 130 of memory cells, also referred to as a memory array 130, host 110, PUs 102-1, 102-2, and/or the bank controller 140 (e.g., the controller 140) might also be separately considered an “apparatus.”

In this example, system 100 includes a host 110 coupled to memory device 120 via an interface 156. The computing system 100 can be a personal laptop computer, a desktop computer, a digital camera, a mobile telephone, a memory card reader, or an Internet-of-Things (IOT) enabled device, among various other types of systems. Host 110 can include a number of processing resources (e.g., one or more processors, microprocessors, or some other type of controlling circuitry) capable of accessing memory 120. The system 100 can include separate integrated circuits, or both the host 110 and the memory device 120 can be on the same integrated circuit. For example, the host 110 may be a system controller of a memory system comprising multiple memory devices 120, with the system controller 110 providing access to the respective memory devices 120 by another processing resource such as a central processing unit (CPU).

In the example shown in FIG. 1, the host 110 is responsible for executing an operating system (OS) and/or various applications that can be loaded thereto (e.g., from memory device 120 via controller 140). The host 110 can provide access commands and/or security mode initialization commands to a memory device via the interface 156.

For clarity, the system 100 has been simplified to focus on features with particular relevance to the present disclosure. The memory array 130 can be a DRAM array, SRAM array, STT RAM array, PCRAM array, TRAM array, RRAM array, NAND flash array, and/or NOR flash array, for instance. The array 130 can comprise memory cells arranged in rows coupled by access lines (which may be referred to herein as word lines or select lines) and columns coupled by sense lines (which may be referred to herein as digit lines or data lines). Although a single array 130 is shown in FIG. 1, embodiments are not so limited. For instance, memory device 120 may include a number of arrays 130 (e.g., a number of banks 130 of DRAM cells).

The memory device 120 includes address circuitry to latch address signals provided over the interface 156. The interface 156 can include, for example, a physical interface employing a suitable protocol (e.g., a data bus, an address bus, and a command bus, or a combined data/address/command bus). Such protocol may be custom or proprietary, or the interface 156 may employ a standardized protocol, such as Peripheral Component Interconnect Express (PCIe), Gen-Z, CCIX, or the like. Address signals are received and decoded by a row decoder 146 and a column decoder 152 to access the memory array 130. Data can be read from memory array 130 by sensing voltage and/or current changes on the sense lines using sensing circuitry. The sensing circuitry can comprise, for example, sense amplifiers that can read and latch a page (e.g., row) of data from the memory array 130. The I/O circuitry can be used for bi-directional data communication with host 110 over the interface 156. Read/write circuitry is used to write data to the memory array 130 or read data from the memory array 130.

Controller 140 decodes signals provided by the host 110. These signals can include chip enable signals, write enable signals, and address latch signals that are used to control operations performed on the memory array 130, including data read, data write, and data erase operations. In various embodiments, the controller 140 is responsible for executing instructions from the host 110. The controller 140 can comprise a state machine, a sequencer, and/or some other type of control circuitry, which may be implemented in the form of hardware, firmware, or software, or any combination of the three.

In various instances, the controller 140 can receive signals provided by the host 110 including signals requesting operations to be performed by the PUs 102-1, 102-2, referred to herein as PUs 102. The PUs 102 can include hardware and/or firmware for performing operations, such as, for example, multiplication operations, using data provided by the memory array 130 or the host 110.

In various examples, error correction code (ECC) circuitry 103 can receive data from the memory array 130. The ECC circuitry 103 can perform error correction operations to correct errors in data sensed from the memory array 130. The PUs 102 can be coupled to the ECC circuitry 103. The PUs 102 can perform a plurality of operations on data received from the ECC circuitry 103. The PUs 102 can provide an output to the data path 104 or the bank 130. The data path 104 can provide data to the interface 156.

In various examples, the PUs 102 can receive data from the bank 130 concurrently. The PUs 102 can also provide data to the bank 130 concurrently. The bank 130 may be configured to provide data to the PUs 102 utilizing a plurality of sense amplifier strips and a plurality of DSA units. The sense amplifier strips can be implemented as part of the sensing circuitry.

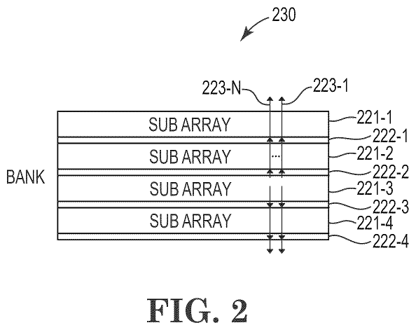

FIG. 2 is a block diagram illustrating a plurality of subarrays 221-1, 221-2, 221-3, 221-4 in accordance with a number of embodiments of the present disclosure. The subarrays 221-1, 221-2, 221-3, 221-4 can be referred to as subarrays 221. The subarrays 221 can be part of the bank 230 (e.g., the array 230 of memory cells). The subarrays 221 can be coupled to the sense amplifier strips 222-1, 222-2, 222-3, 222-4, referred to as sense amplifier strips 222.

For example, the sense amplifier strip 222-1 can be coupled to the subarray 221-1. The sense amplifier strip 222-2 can be coupled to the subarray 221-2. The sense amplifier strip 222-3 can be coupled to the subarray 221-3. The sense amplifier strip 222-4 can be coupled to the subarray 221-4.

Each of the sense amplifier strips 222 can include a plurality of sense amplifiers and a number of multiplexors (MUXs). The sense amplifiers of the sense amplifier strips 222 can be coupled to the sense lines of the subarrays 221. A quantity of the sense amplifiers can be equal to the quantity of sense lines of the subarrays 221. The MUXs of the sense amplifier strips 222 can be used to select a number of columns of the bank 230 to sense (e.g., read) out of the bank 230. The data that is output from the sense amplifier strips 222 can be referred to as the prefetch data.

The subarrays 221 can be divided into a plurality of portions. For example, a first portion of the subarrays 221 can include the subarrays 221-1, 221-2. The second portion of the subarrays 221 can include the subarrays 221-3, 221-4. The subarrays 221 can be divided into portion to output more data than if the subarrays 221 were not divided. For example, if the subarrays 221 are divided into two portions, then the subarrays 221 can output more data than if the subarrays 221 are not divided into portions. The subarrays 221 that are divided into two portions can provide double the prefetch data than subarrays 221 that are not divided into portions. For example, if a row of the subarrays 221 includes 8,192 memory cells, then the sense amplifier strips 222 can output 256 bits of data if the subarrays 221 are not divided. If the subarrays 221 are divided, then the sense amplifier strips 222 can output 512 bits of data.

The sense amplifier strips 222 can be coupled to the local data lines 223-1, . . . , 223-N, referred to as local data lines 223. For example, the sense amplifier strip 222-1 can be coupled to the local data lines 223. The sense amplifier strip 222-2 can be coupled to the local data lines 223. The sense amplifier strip 222-3 can be coupled to the local data lines 223. The sense amplifier strip 222-4 can be coupled to the local data lines 223. As used herein, local data lines include data lines internal to the bank 230. Global data lines include data lines external to the bank 230.

The local data lines 223 are shown as providing data in opposite direction by the arrows that point in opposite directions. For example, the local data lines 223 are shown as providing data towards the top of the page where the sense amplifier strips 222-1, 222-2 are coupled to the local data lines 223. The local data lines 223 are also shown as providing data towards the bottom of the page where the sense amplifier strips 222-3, 222-4 are coupled to the local data lines 223. The direction of the arrows shown along the local data lines 223 is illustrative and not intended to be limiting.

The direction of the arrows of the local data lines 223 is used to illustrate that the sense amplifier strips 222 provide data to different PUs using the segmented local data lines. For example, the sense amplifier strips 222-1, 222-2 can provide data to a first PU via a first DSA unit (not shown). The sense amplifier strips 222-3, 222-4 can be provide data to a second PU via a second DSA unit (not shown).

The quantity of subarrays 221 shown is not intended as limiting. The quantity of subarrays 221 is shown to illustrate the division of the subarrays 221 into two or more portions. Although the examples shown herein are provided in the context of subarrays 221 and the bank 230 being divided into two portions, the subarrays 221 and the bank 230 can be divided into three or more portions. Although four local data lines 223 are shown, the local data lines 223 can include more or less data lines than those shown. For example, the local data lines 223 can include 512 local data lines given that the first portion of the subarrays 221 can provide 256 bits of data and the second portion of the subarrays 221 can provide a different 256 bits of data.

The sense amplifier strips 222 can receive data from the array of memory cells. The array of memory cells can provide the first data to the first sense amplifier strip and the second data to the second sense amplifier strip via a plurality of sense lines, concurrently. The sense lines can couple the sense amplifier strips 222 to the memory cells to the bank 230.

The sense amplifier strips 222 can receive data from the subarrays 221. The sense amplifier strip 222-1 can receive data from the subarray 221-1. The sense amplifier strip 222-2 can receive data from the subarray 221-2. The sense amplifier strip 222-3 can receive data from the subarray 221-3. The sense amplifier strip 222-4 can receive data from the subarray 221-4.

The sense amplifier strips 222 can provide data to the PUs using the address provided by the column decoder. For example, the sense amplifier strips 222-1, 222-2 can provide first data to the first PU. The sense amplifier strips 222-3, 222-4 can provide second data to the second PU. The sense amplifier strips 222 can provide data using the address provided by the column decoder. The column decoder can provide the address (e.g., column address) to the sense amplifier strips 222 where the sense amplifier strips provide data to different DSA and PUs.

The plurality of local data lines 223 can couple to the first sense amplifier strip to the first PU. The plurality of local data lines 223 can couple the second sense amplifier strip to the second PU. The plurality of local data lines 223 can allow the first sense amplifier strip to provide first data to the first PU and the second sense amplifier strip to provide second data to the second PU concurrently. The plurality of local data lines 223 can be segmented such that a first portion of the plurality of local data lines 223 can provide data concurrently with a second portion of the plurality of local data lines 223. Data may not be provided from the first portion of the plurality local data lines 223 to the second portion of the plurality of local data lines 223. For example, the first portion of the local data lines 223 may be segmented from the second portion of the local data lines 223. The first portion of the local data lines 223 can be insulated from the second portion of the local data lines 223 with an insulative material.

The first sense amplifier strip can select the first data, receive from the array of memory cells, using the address prior to providing the first data to the first PU. The second sense amplifier strip can select the second data, received from the array of memory cells, using the address prior to providing the second data to the second PU. The first sense amplifier strip can provide the first data to the first PU and the second sense amplifier strip can provide the second data to the second PU, concurrently. The first PU can perform a first plurality of operations using the first data and the second PU can perform a second plurality of operation using the second data, where the first plurality of operations and the second plurality of operations are performed concurrently.

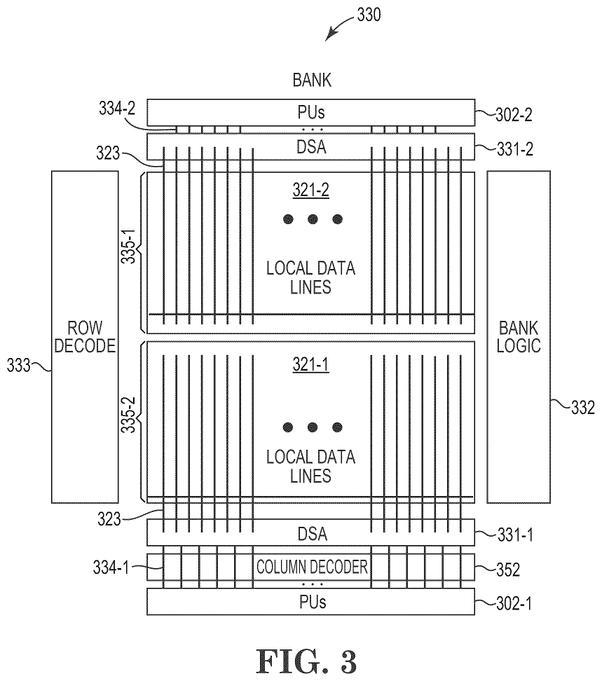

FIG. 3 is a block diagram illustrating a bank 330 in accordance with a number of embodiments of the present disclosure. The bank 330 includes PUs 302-1, 302-2, subarrays 321-1, 321-2, local data lines 323, DSA units 331-1, 331-2, bank logic 332, a row decoder 333, global data lines 334-1, 334-2, and a column decoder 352. The bank 330 can correspond to bank 130 of FIG. 1 and bank 230 of FIG. 2. The subarrays 321-1, 321-2 can correspond to subarrays 221 of FIG. 2. Local data lines 323 can correspond to local data lines 223 of FIG. 2. The PUs 302-1, 302-2 can correspond to PUs 102-1, 102-2 and the column decoder 352 can correspond to the column decoder 152 of FIG. 1. As used herein, the bank logic 332 can include hardware for controlling the activation of the PUs 302-1, 302-2, the row decoder 333, the column decoder 352, the sense amplifier strips (e.g., sense amplifier strips 222 of FIG. 2), and the DSA units 331-1, 331-2, referred to as DSA units 331.

In various examples, a mode of the bank 330 can be used to determine whether the subarrays 321, are configured to provide data to the DSA units 331. For example, in a first mode, a first sense amplifier strip can provide first data to the DSA unit 331-1 using the first column address and a second sense amplifier strip can refrain from providing the second data to the DSA unit 331-2. In a second mode the first sense amplifier strip can provide the first data to the DSA unit 331-1 using the first column address and the second sense amplifier strip can provide the second data to the DSA unit 331-2 using the second column address. The first column address and the second column address can be provided by the column decoder 352.

The bank logic 332 can provide signals to the first sense amplifier strips to cause the first sense amplifier strips to provide the first data to the DSA unit 331-1 if the array is in the first mode or the second mode. The bank logic 332 can provide signals to the second sense amplifier strips to cause the second sense amplifier strips to provide the second data to the DSA unit 331-2 if the array is in the second mode. The bank logic 332 can provide signals to the second sense amplifier strips to cause the second sense amplifier strips to refrain from providing the second data to the DSA unit 331-2 if the array is in the first mode. The DSA unit 331-1 can provide the first data to a PU 302-1 if the array is in the first mode or the second mode. The DSA unit 331-2 can provide the second data to the PU 302-2 if the array is in the second mode. The DSA unit 331-2 can refrain from providing the second data to the PU 302-2 if the array is in the first mode.

Although, the first sense amplifier strips are described as providing data regardless of whether the bank 330 is in the first mode or the second mode and the second sense amplifier strips are describes a providing data if the bank is in the first mode and refraining from providing data if the bank 330 is in the second mode. The first sense amplifier strips and the second sense amplifier strips as described herein are interchangeable. For example, the second sense amplifier strips can provide data regardless of whether the bank 330 is in the first mode or the second mode and the first sense amplifier strips can provide data if the bank is in the first mode and refrain from providing data if the bank 330 is in the second mode.

In various examples, the row decoder 333 can activate rows of the subarrays 321 that have the same row addresses or rows of the subarrays 321 that have different row addresses. For example, if the bank 330 is in the first mode, then the row decoder 333 can activate a first row of memory cells in subarray 321-1 and a second row of memory cells in the subarray 321-2 that have a same address. If the bank 330 is in the first mode, then the row decoder 333 can activate a first row of memory cells in the subarray 321-1 and a second row of memory cells in the subarray 321-2 that have different addresses.

In the first mode, data provided by the first sense amplifier strips can be provided to the PU 302-1 or to the pins of the memory device. For example, the data may be provided by the sense amplifier strips to the DSA unit 331-1. The DSA unit 331-1 can provide the data to the PU 302-1.

In the second mode, data provided by the sense amplifier strips can be provided to the PUs 302 but may not be provided to the pins of the memory device. For example, the first sense amplifier strips can provide data to the DSA unit 331-1. The second sense amplifier strips can provide data to the DSA unit 331-2. The DSA unit 331-1 can provide data to the PU 302-1. The DSA unit 331-2 can provide data to the PU 302-2. Neither of the DSAs 331-1, 331-2 may provide data to the pins of the memory device while the bank 330 is in the first mode.

Responsive to receiving data, the sense amplifier strips can receive a column address from the column decoder 352. The column decoder 352 can provide an address to the first sense amplifier strips and the second sense amplifier strips. For example, the column decoder 352 can provide a column address to the first sense amplifier strips and the second sense amplifier strips. The column decoder 352 can provide the address responsive to being activated by the bank logic 332. The sense amplifier strips of the subarrays 321 can select a data from the data received from the memory cells of the subarrays 321 utilizing the address and can provide the selected data to the DSA units 331. For example, if first data is received from the memory cells of the subarrays 321, the sense amplifier strips can select, using a plurality of MUXs, a subset of the first data and provide the subset of the first data to the DSA units 331. The subset of the first data provided from the first sense amplifier strips can include 256 bits and the subset of the second data provided from the second sense amplifier strips can include 256 bits, for example.

The sense amplifier strips can provide data to the DSA units 331 via the local data lines 323. The local data lines 323 can be segmented into different portions 335-1, 335-2 of the local data lines 323. The portions 335-1, 335—can be referred to as portions 335. The first sense amplifier strips can provide first data to the DSA unit 331-1 via a portion 335-1 of the local data lines 323. The second sense amplifier strips can provide second data to the DSA unit 331-2 via the portion 335-2 of the local data lines 323.

The DSA unit 331 can receive data from the sense amplifier strips of the memory array of the memory device. The DSA unit 331-1 can receive the first data from the first sense amplifier strips and the DSA unit 331-2 can receive the second data from the second sense amplifier strips concurrently.

Both the DSA units 331 can be implemented in the bank 330. The bank logic 332 can be configured to control the DSA units 331 and the timing of the DSA units 331. The bank logic 332 can provide signals to the first sense amplifier strips and the second sense amplifier strip to cause the first sense amplifier strips and the second sense amplifier strips to provide the first data and the second data to the DSA unit 331-1 and the DSA unit 331-2, respectively.

Responsive to receiving data, the DSA units 331 can provide the received data to the PU 302-1, 302-2, referred to as PUs 302. The DSA units 331 can provide the received data utilizing global data lines 334-1, 334-2, referred to as global data lines 334. For example, the DSA unit 331-1 can provide data to the PU 302-1 via the global data lines 334-1. The DSA unit 331-2 can provide data to the PU 302-2 via the global data lines 334-2. The global data lines 334-1 and the global data lines 334-2 can be part of the bank 330. The global data lines 334-1 can couple the DSA unit 331-1 to the first PU 302-1 and the global data lines 334-2 can couple the DSA unit 331-2 to the second PU 302-2.

The bank 330 can be implemented with a single column decoder 352, a single row decoder 333, and a single bank logic 332. The bank 330 can be implemented with multiple DSA units 331 and multiple PUs 302. The sense amplifier strips can be configured differently based on whether the sense amplifier strips are located in the subarrays 321-1 or the subarrays 321-2. For example, the sense amplifier strips in the subarrays 321-1 can route data to the DSA unit 331-1. The sense amplifier strips in the subarrays 321-2 can route data to the DSA unit 331-2.

In previous approaches, the local data lines and global data lines of the bank 330 may be used to provide data to the DSA 331-1. In a number of examples, twice as many global data lines can be utilized to provide data to the DSAs 331 as compared to the global data lines of banks of previous approaches. Additionally, twice as many DSAs 331 and PUs 302 are implemented in the examples described herein as compared to previous approaches that implement a single DSA and a single PU. Although the examples described herein utilize two DSA units 331 and two PUs 302, more than two DSA units and the PUs can be implemented by dividing the bank 330 into three or more portions of subarrays.

In a number of instances, data can also be stored back to the bank 330 utilizing the PUs 302, the DSAs unit 331, the global data lines 334, and the local data lines 323. For example, the output of the PUs 302 can be provided to the DSA units 331. The output data generated by the PU 302-1 can be provided to the DSA unit 331-1 via the global data lines 334-1 and the output data generated by the PU 302-2 can be provided to the DSA unit 331-2 via the global data lines 334-2.

The DSAs 331 can provide data to the sense amplifier strips. For example, the DSA 331-1 can provide data to the first sense amplifier strip via the portion 335-1 of the local data lines 323. The DSA 331-2 can provide data to the second sense amplifier strip via the second portion 335-1 of the local data lines 323. The first sense amplifier strip can be used to store data to the subarray 321-1 via the sense lines. The second sense amplifier strip can be used to store data to the subarray 321-2 via the sense lines.

The examples described herein allow for twice as much data to be stored to the subarrays 321 than previous approaches. Utilizing twice as many global data lines 334 allows for twice as much data to be stored in the bank 330.

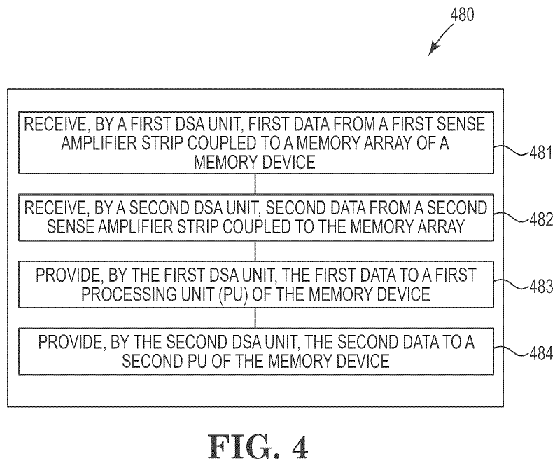

FIG. 4 illustrates an example flow diagram of a method 480 for performing a double bank prefetch in accordance with a number of embodiments of the present disclosure. The method can be performed by a memory device of a computing system, such as, for instance memory device 120 of computing system 100 previously described in connection with FIG. 1.

At 481, a first DSA unit can receive first data from a first sense amplifier strip coupled to a memory array of a memory device. The first DSA unit can receive the first data via local data lines that couple the first DSA unit to the first sense amplifier strip. The first DSA unit is analogous to the DSA unit 331-1 of FIG. 3. The memory device is analogous to the memory device 120 of FIG. 1.

At 482, a second DSA unit can receive second data from a second sense amplifier strip coupled to the memory array. The second DSA unit can receive the second data via local data lines that couple the second DSA to the second sense amplifier strip. The second DSA unit is analogous to the DSA unit 331-2 of FIG. 3.

At 483, the first DSA unit can provide the first data to a first PU of the memory device. The first DSA unit can provide the first data to the first PU via a first plurality of a global data lines. The first plurality of global data lines can couple the first DSA unit to the first PU.

At 484, the second DSA unit can provide the second data to a second PU of the memory device. The second DSA unit can provide the second data to the second PU via a second plurality of global data lines. The second plurality of global data lines couple the second DSA unit to the second PU. The first PU is analogous to the PUs 102-1, 302-1 and the second PU is analogous to the PUs 102-2, 302-2 of FIGS. 1 and 3, respectively. The first DSA unit can receive the first data from the first sense amplifier strip and the second DSA unit can receive the second data from the second sense amplifier strip concurrently.

The bank logic can provide signals to the first sense amplifier strip and the second sense amplifier strip to cause the first sense amplifier strip and the second sense amplifier strip to provide the first data and the second data to the first DSA and the second DSA. The bank logic is analogous to the bank logic 335 of FIG. 3.

In various examples, an apparatus can include an array of memory cells, a column decoder, a first sense amplifier strip, and a second sense amplifier strip. The column decoder can provide an address to a first sense amplifier strip and a second sense amplifier strip. The first sense amplifier strip can be coupled to the array of memory cells and the column decoder. The first sense amplifier strip can receive first data from the array of memory cells and can provide the first data to a first PU of the apparatus using the address. The second sense amplifier strip can be coupled to the array of memory cells and the column decoder. The second sense amplifier strip can receive second data from the array of memory cells and can provide the second data to a second PU using the address. The first sense amplifier strip is analogous to the sense amplifier strip 222-1 and the second sense amplifier strip is analogous to the sense amplifier strip 222-2 of FIG. 2.

The array of memory cells can provide the first data to the first sense amplifier strip and the second data to the sense amplifier strip. The first sense amplifier strip can receive the first data from the array of memory cells and second sense amplifier strip can receive the second data from the array of memory cells via a plurality of sense lines.

The first sense amplifier strip can provide the first data to the first PU via a plurality of local data lines. The second sense amplifier strip can provide the second data to the second PU via the plurality of local data lines. The first sense amplifier strip can provide the first data to the first PU via the plurality of local data lines concurrently with the providing of the second data by the second sense amplifier strip to the second PU via the plurality of local data lines. Plurality of local data lines can be segmented such that a first portion of the plurality of local data lines couple the first sense amplifier strip to the first PU and a second portion of the second plurality of local data lines couple the second sense amplifier strip to the second PU. The first portion of the plurality of local data lines can be adjacent to the second portion of the plurality of local data lines. The segmentation of the first portion of the plurality of local data lines from the second portion of the plurality of local data lines can prevent signals from being provided from the first portion of the plurality of local data lines to the second portion of the plurality of local data lines and from the second portion of the plurality of local data lines to the first portion of the plurality of local data lines.

The first sense amplifier strip and the second sense amplifier strip can receive the address from a single column decoder. The first sense amplifier strip can select the first data, received from the array of memory cells, using the address prior to providing the first data to the first PU. The second sense amplifier strip can select the second data, received from the array of memory cells, using the address prior to providing the second data to the second PU.

The first sense amplifier strip can provide the first data to the first PU and the second sense amplifier strip can provide the second data to the second PU concurrently. The first PU can perform a first plurality of operations using the first data. The second PU can perform a second plurality of operations using the second data. The first plurality of operations and the second plurality of operations can be performed concurrently.

In various examples, a system can include an array of memory cells, a column decoder, a first sense amplifier strip, and a second sense amplifier strip. The column decoder can provide the first column address to a first sense amplifier strip and a second column address to the second sense amplifier strip. The first sense amplifier strip can be coupled to the array and the column decoder. The second sense amplifier strip can also be coupled to the array and the column decoder.

The first sense amplifier strip can receive first data from the array of memory cells. Responsive to the array of memory cells being in a first mode or a second mode, the first sense amplifier strip can provide the first data to a first data sense amplifier (DSA) unit of the system using the first column address.

The second sense amplifier strip can receive second data from the array of memory cells. The second sense amplifier strip can, responsive to the array of memory cells being in the first mode, refrain from providing the second data to a second DSA unit of the system. The second sense amplifier strip can, responsive to the array of memory cells being in the second mode, provide the second data to a second DSA unit using the second column address.

Bank logic of the bank can be coupled to the array of memory cells. The bank logic can provide a signal to the second sense amplifier strip to cause the second sense amplifier strip to provide the second data to the second DSA unit responsive to the array of memory cells being in the second mode. The bank logic can provide a signal to the second sense amplifier strip to cause the second sense amplifier strip to refrain from providing the second data to the second DSA unit responsive to the array of memory cells being in the first mode. A first DSA unit can provide the first data to a first PU of the system responsive to the array being in a first mode or a second mode. The second DSA unit can provide the second data to a second PU responsive to the array being the second mode and can refrain from providing the second data to the second PU responsive to the array being in the first mode.

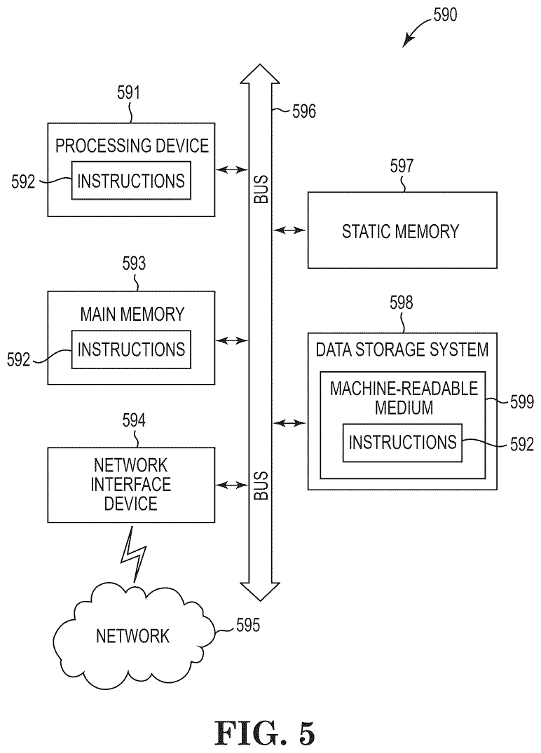

FIG. 5 illustrates an example machine of a computer system 590 within which a set of instructions, for causing the machine to perform any one or more of the methodologies discussed herein, can be executed. In some embodiments, the computer system 590 can correspond to a host system (e.g., the host 110 of FIG. 1) that includes, is coupled to, or utilizes a memory system (e.g., the memory device 120 of FIG. 1) or can be used to perform the operations of the controller, the PUs, the sense amplifier strips, and the DSA units (e.g., the controller 140, the PUs 102 of FIG. 1, the sense amplifier strips 222 of FIG. 2, and the DSA units 331 of FIG. 3). In alternative embodiments, the machine can be connected (e.g., networked) to other machines in a LAN, an intranet, an extranet, and/or the Internet. The machine can operate in the capacity of a server or a client machine in client-server network environment, as a peer machine in a peer-to-peer (or distributed) network environment, or as a server or a client machine in a cloud computing infrastructure or environment.

The machine can be a personal computer (PC), a tablet PC, a set-top box (STB), a Personal Digital Assistant (PDA), a cellular telephone, a web appliance, a server, a network router, a switch or bridge, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methodologies discussed herein.

The example computer system 590 includes a processing device 591, a main memory 593 (e.g., read-only memory (ROM), flash memory, dynamic random access memory (DRAM) such as synchronous DRAM (SDRAM) or Rambus DRAM (RDRAM), etc.), a static memory 597 (e.g., flash memory, static random access memory (SRAM), etc.), and a data storage system 598, which communicate with each other via a bus 596.

Processing device 591 represents one or more general-purpose processing devices such as a microprocessor, a central processing unit, or the like. More particularly, the processing device can be a complex instruction set computing (CISC) microprocessor, reduced instruction set computing (RISC) microprocessor, very long instruction word (VLIW) microprocessor, or a processor implementing other instruction sets, or processors implementing a combination of instruction sets. Processing device 591 can also be one or more special-purpose processing devices such as an application specific integrated circuit (ASIC), a field programmable gate array (FPGA), a digital signal processor (DSP), network processor, or the like. The processing device 591 is configured to execute instructions 592 for performing the operations and steps discussed herein. The computer system 590 can further include a network interface device 594 to communicate over the network 595.

The data storage system 598 can include a machine-readable storage medium 599 (also known as a computer-readable medium) on which is stored one or more sets of instructions 592 or software embodying any one or more of the methodologies or functions described herein. The instructions 592 can also reside, completely or at least partially, within the main memory 593 and/or within the processing device 591 during execution thereof by the computer system 590, the main memory 593 and the processing device 591 also constituting machine-readable storage media.

In one embodiment, the instructions 592 include instructions to implement functionality corresponding to the PUs 102 of FIG. 1, the sense amplifier strips 222 of FIG. 2, and the DSA units 331 of FIG. 3. While the machine-readable storage medium 599 is shown in an example embodiment to be a single medium, the term “machine-readable storage medium” should be taken to include a single medium or multiple media that store the one or more sets of instructions. The term “machine-readable storage medium” shall also be taken to include any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, optical media, and magnetic media.

Although specific embodiments have been illustrated and described herein, those of ordinary skill in the art will appreciate that an arrangement calculated to achieve the same results can be substituted for the specific embodiments shown. This disclosure is intended to cover adaptations or variations of various embodiments of the present disclosure. It is to be understood that the above description has been made in an illustrative fashion, and not a restrictive one. Combinations of the above embodiments, and other embodiments not specifically described herein will be apparent to those of skill in the art upon reviewing the above description. The scope of the various embodiments of the present disclosure includes other applications in which the above structures and methods are used. Therefore, the scope of various embodiments of the present disclosure should be determined with reference to the appended claims, along with the full range of equivalents to which such claims are entitled.

In the foregoing Detailed Description, various features are grouped together in a single embodiment for the purpose of streamlining the disclosure. This method of disclosure is not to be interpreted as reflecting an intention that the disclosed embodiments of the present disclosure have to use more features than are expressly recited in each claim. Rather, as the following claims reflect, inventive subject matter lies in less than all features of a single disclosed embodiment. Thus, the following claims are hereby incorporated into the Detailed Description, with each claim standing on its own as a separate embodiment.

What is claimed is:

1. An apparatus, comprising:
an array of memory cells;
a column decoder configured to provide an address to a first sense amplifier strip and a second sense amplifier strip;
the first sense amplifier strip, wherein the first sense amplifier strip is coupled to the array of memory cells and the column decoder and is configured to:
receive first data from the array of memory cells; and
provide the first data to a first processing unit (PU) of the apparatus using the address; and
the second sense amplifier strip, wherein the second sense amplifier strip is coupled to the array of memory cells and the column decoder and is configured to:
receive second data from the array of memory cells; and
provide the second data to a second PU of the apparatus using the address.

2. The apparatus of claim 1, wherein the first sense amplifier strip is configured to receive the first data from the array of memory cells and the second sense amplifier strip is configured to receive the second data from the array of memory cells via a plurality of sense lines.

3. The apparatus of claim 2, wherein:
the first sense amplifier strip is configured to provide the first data to the first PU via a plurality of local data lines; and
the second sense amplifier strip is configured to provide the second data to the second PU via the plurality of local data lines, concurrently.

4. The apparatus of claim 3, wherein a first portion of the plurality of local data lines couple the first sense amplifier strip to the first PU and a second portion of the plurality of local data lines couple the second sense amplifier strip to the second PU.

5. The apparatus of claim 1, wherein the first sense amplifier strip and the second sense amplifier strip are further configured to receive the address from a single column decoder.

6. The apparatus of claim 1, wherein:
the first sense amplifier strip is further configured to select the first data, received from the array of memory cells, using the address prior to providing the first data to the first PU; and
the second sense amplifier strip is further configured to select the second data, received from the array of memory cells, using the address prior to providing the second data to the second PU.

7. The apparatus of claim 1, wherein the first sense amplifier strip is configured to provide the first data to the first PU and the second sense amplifier strip is configured to provide the second data to the second PU concurrently.

8. The apparatus of claim 1, wherein:
the first PU is configured to perform a first plurality of operations using the first data; and
the second PU is configured to perform a second plurality of operations using the second data.

9. The apparatus of claim 8, wherein the first plurality of operations and the second plurality of operations are performed concurrently.

10. A method, comprising:
receiving, by a first data sense amplifier (DSA) unit, first data from a first sense amplifier strip coupled to a memory array of a memory device;
receiving, by a second DSA unit, second data from a second sense amplifier strip coupled to the memory array;
providing, by the first DSA unit, the first data to a first processing unit (PU) of the memory device; and
providing, by the second DSA unit, the second data to a second PU of the memory device.

11. The method of claim 10, wherein the first data is provided to the first PU via a first plurality of global data lines.

12. The method of claim 11, wherein the second data is provided to the second PU via a second plurality of global data lines.

13. The method of claim 12, wherein the first plurality of global data lines couple the first DSA unit to the first PU and the second plurality of global data lines couple the second DSA unit to the second PU.

14. The method of claim 10, further comprising receiving, by the first DSA unit, the first data from the first sense amplifier strip and receiving, by the second DSA unit, the second data from the second sense amplifier strip, concurrently.

15. The method of claim 10, further comprising providing signals from bank logic to the first sense amplifier strip and the second sense amplifier strip to cause the first sense amplifier strip and the second sense amplifier strip to provide the first data and the second data to the first DSA and the second DSA.

16. A system, comprising:
an array of memory cells;
a column decoder configured to provide a first column address to a first sense amplifier strip and a second column address to a second sense amplifier strip;
the first sense amplifier strip, wherein the first sense amplifier strip is coupled to the array of memory cells and the column decoder and is configured to:
receive first data from the array of memory cells; and
responsive to the array of memory cells being in a first mode or a second mode, provide the first data to a first data sense amplifier (DSA) unit of the system using the first column address; and
the second sense amplifier strip, wherein the second sense amplifier strip is coupled to the array of memory cells and the column decoder and is configured to:
receive second data from the array of memory cells;
responsive to the array of memory cells being in the first mode,
refrain from providing the second data to a second DSA unit of the system; and
responsive to the array of memory cells being in the second mode, provide the second data to the second DSA unit using the second column address.

17. The system of claim 16, further comprising bank logic coupled to the array of memory cells and configured to provide a signal to the second sense amplifier strip to cause the second sense amplifier strip to provide the second data to the second DSA unit responsive to the array of memory cells being in the second mode.

18. The system of claim 16, further comprising bank logic coupled to the array of memory cells and configured to provide a signal to the second sense amplifier strip to cause the second sense amplifier strip to refrain from providing the second data to the second DSA unit responsive to the array of memory cells being in the first mode.

19. The system of claim 16, wherein the first DSA unit is configured to:
provide the first data to a first processing unit (PU) of the system responsive to the array being in the first mode or the second mode.

20. The system of claim 19, wherein the second DSA unit is configured to:
provide the second data to a second PU of the system responsive to the array being in the second mode; and
refrain from providing the second data to the second PU responsive to the array being in the first mode.
